(19) United States
(12) Patent Application Publication
(10) Pub. No.: US 2026/0031134 A1
(43) Pub. Date: Jan. 29, 2026

(54) DIFFERENTIAL LATCH SENSE AMPLIFIER

(71) Applicant: Micron Technology, Inc., Boise, ID (US)

(72) Inventor: Daniele Vimercati, El Dorado Hills, CA (US)

(21) Appl. No.: 18/783,095

(22) Filed: Jul. 24, 2024

(51) Int. Cl. G11C 11/4091

(52) U.S. Cl. CPC G11C 11/4091

(57) ABSTRACT

A typical DRAM stores gigabytes (GB) of data, with tens or hundreds of billions of memory cells. With so many cells, thousands or millions of cells exhibit operating characteristics that are multiple standard deviations from nominal. A sense amplifier receives as input the two differential bitlines of a DRAM column. Each of two portions of the sense amplifier handles a respective one of the bitlines, and the bitline signals are compared to generate the digital output of the sense amplifier. Variation between sense amplifiers may be expressed as a voltage offset in one or both portions. The voltage offset may be compensated for by biasing the comparison. As described herein, the voltage difference can be compensated for on one bitline. As a result, the variation in the voltage swing in different components is substantially reduced and read reliability is improved.

### TECHNICAL FIELD

Embodiments of the disclosure relate generally to sense amplifiers and more specifically to systems and methods for reducing an error rate of reading data from memory cells using a differential latch sense amplifier.

### BACKGROUND

Dynamic random access memory (DRAM) stores one bit of data in each memory cell. Each memory cell includes a capacitor and a transistor. The amount of charge held by the capacitor indicates whether the cell is storing a zero value or a one value. To read the data from the cell, the transistor is activated, allowing the stored charge in the capacitor to affect the voltage of a read line.

A sense amplifier is used to read the data value from the memory cell by comparing the voltage resulting from the charge stored by the memory cell with a nominal voltage. In practice, the large number of memory cells and sense amplifiers in a memory device results in substantial deviations from ideal behavior. As a result, in a large memory device, many memory cells may be unreliable.

### BRIEF DESCRIPTION OF THE SEVERAL VIEWS OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

To easily identify the discussion of any particular element or act, the most significant digit or digits in a reference number refer to the figure number in which that element is first introduced.

FIG. 1 is a schematic diagram of an example DRAM device according to various embodiments.

FIG. 2 provides a block diagram of an example system including a memory system.

FIG. 3 illustrates an example DRAM sense amplifier for use in a DRAM device.

FIG. 4 illustrates a graph showing a range of voltage offsets due to device variation and a graph showing that even after compensating for the voltage offsets, charge sharing is affected by the device variation in a DRAM sense amplifier.

FIG. 5 illustrates an example DRAM differential latch sense amplifier for use in a DRAM device.

FIGS. 6-9 illustrate the example DRAM differential latch sense amplifier during different stages of operation.

FIG. 10 illustrates a graph showing a constant voltage offset despite variation and its effect on charge sharing in a DRAM differential latch sense amplifier.

FIG. 11 is a flow chart showing operations of a method performed by a DRAM differential latch sense amplifier, in accordance with some embodiments of the present disclosure.

### DETAILED DESCRIPTION

A semiconductor device is an electronic component that relies on the electronic properties of a semiconductor material (primarily silicon, germanium, and gallium arsenide, as well as organic semiconductors) for its function. Example semiconductor devices include discrete devices and integrated circuits (ICs), which comprise two or more devices (e.g., hundreds, thousands, millions, or billions of transistors in a single IC) interconnected on a single semiconductor substrate.

A DRAM device is composed of memory cells, usually arranged in a two-dimensional grid. A typical DRAM stores gigabytes (GB) of data, with tens or hundreds of billions of memory cells. Assuming that the properties of the memory cells are distributed on a bell curve, with so many cells, thousands or millions of cells will be five standard deviations (5σ) or more from nominal. Within a sense amplifier, deviation from normal may be seen as a bias toward providing a particular output.

The sense amplifier receives as input the two differential bitlines of a DRAM column. Each of two portions of the sense amplifier handles one of the two bitlines, and the resulting signals are compared to generate the digital output of the sense amplifier. Variation between sense amplifiers may be expressed as a voltage offset in one or both portions. If the voltage offset exceeds the voltage swing between the differential bitlines, the sense amplifier always provides the same output regardless of the inputs.

To measure the voltage offset, the sense amplifier may be initialized by connecting both bitlines to the same voltage (e.g., halfway between the operating voltage and the reference voltage) and determining the voltage differential that is received at the point of comparison. Compensation for a voltage offset may be provided by biasing an input of the sense amplifier.

Even after applying the bias, however, the voltage change detected at the point of comparison is not constant during charge sharing. The voltage swing may vary by 50% or more between a +5σ component and a -5σ component. As described herein, the voltage difference can be compensated on one bitline. As a result, the variation in the voltage swing in different components is substantially reduced.

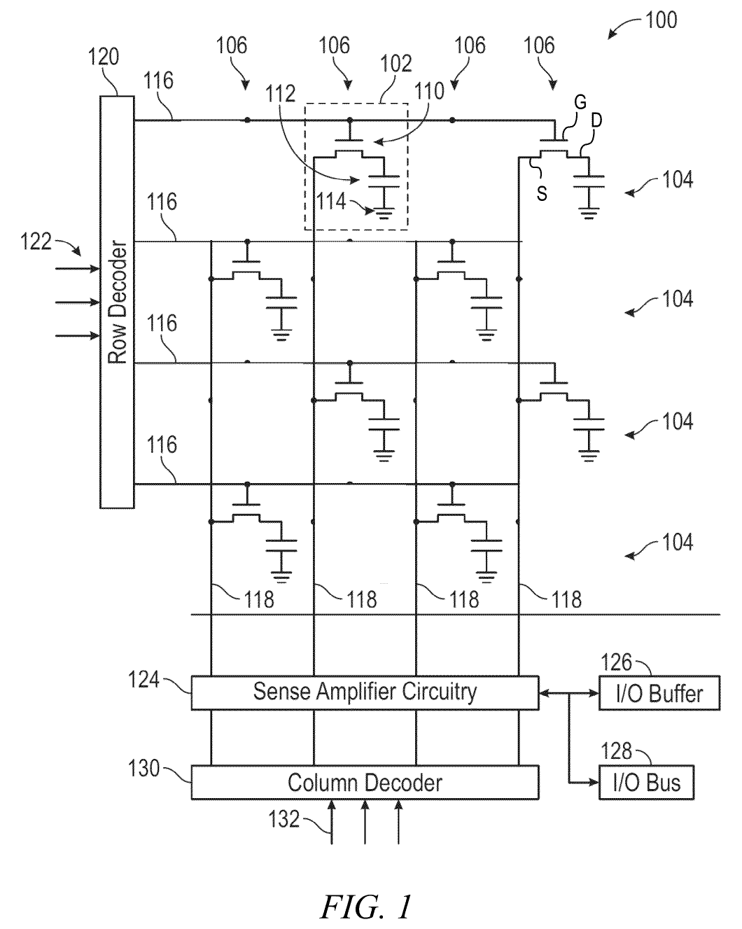

FIG. 1 provides a schematic of an example DRAM memory device 100 according to various embodiments. The device includes an array of memory cells 102 (only one being labeled in FIG. 1 to avoid obfuscation) arranged in rows 104 and columns 106. For simplicity, and sufficiently for purposes of explaining fundamental components and the basic operation of the memory device 100, the array is shown in only two dimensions; the array can be extended into the third dimension. Further, while only four rows 104 and columns 106 are illustrated, it is to be understood that DRAM devices can, in practice, include many more (e.g., tens, hundreds, or thousands of) memory cells 102 per row and/or per column.

In accordance with various embodiments, each memory cell 102 includes a single transistor 110 (e.g., a field effect transistor (FET)) and a single capacitor 112; such a cell is, therefore, also commonly referred to as a 1T1C cell. One plate of the capacitor 112, herein also the “node plate,” is connected to the drain terminal (“D”) of the transistor 110, whereas the other plate of the capacitor 112 is connected to ground 114. Each capacitor 112 within the array of 1T1C cells 102 serves to store one bit of data, and the respective transistor 110 serves as an “access device” to write to or read from the storage capacitor 112.

The transistor gate terminal terminals (“G”) within each row 104 are portions of respective access lines (alternatively referred to as “word lines”) 116 (and may be formed of the same material, or a different material), and the transistor source terminals (“S”) within each column 106 are electrically connected to respective data lines (alternatively referred to as “bit lines”) 118. A row decoder 120 can selectively drive the individual access lines 116, responsive to row address signals 122 input to the row decoder 120. Driving a given access line 116 at an operating voltage (e.g., 1.0 V) causes the access transistors 110 within the respective row 104 to conduct, thereby connecting the storage capacitors 112 within the row 104 to the respective data lines 118, such that charge can be transferred between the data lines 118 and the storage capacitors 112 as required for read or write operations. Both read and write operations can be performed via sense amplifier circuitry 124, which can transfer bit values between the memory cells 102 of the selected row 104 and input/output buffers 126 (for write/read operations) or external input/output data buses 128. A column decoder 130 responsive to column address signals 132 can select which of the memory cells 102 within the selected row 104 is read out or written to. Alternatively, for read operations, the storage capacitors 112 within the row 104 may be read out simultaneously and latched, and the column decoder 130 can then select which latch bits to connect to the output data bus 128. Since read-out of the storage capacitors destroys the stored information, the read operation is accompanied by a rewrite of the capacitor charge. Further, in between read/write operations, the capacitor charge is repeatedly refreshed to prevent data loss. Details of read/rewrite, write, and refresh operations are well-known to those of ordinary skill in the art.

Prior to energizing one of the word lines 116 to read data from the memory cells 102, the bit lines 118 are placed in a neutral state (e.g., at 0.5 V in a memory device with an operating voltage of 1.0 V and a reference voltage of 0.0 V). When a word line 116 is energized, the storage capacitors of the memory cells connected to that word line 116 share their charge with the bit line 118 to which they are attached. For a particular word line 116, the memory cells 102 are connected to either the even-numbered or odd-numbered bit lines. If the memory cell contains a logical 1 value, its capacitor 112 stores a charge that raises the voltage of the bit line to which it is connected. If the memory cell contains a logical 0 value, charge flows from the bit line to which it is connected into the capacitor 112, reducing the voltage of the bit line. The sense amplifier circuitry 124 compares the voltage on each pair of bit lines 118 (e.g., the first two bit lines 118, the third and fourth bit lines 118, and so on). If the bit line 118 that is connected to the memory cell 102 has a higher voltage than the other bit line 118 (still at a neutral voltage), the sense amplifier circuitry 124 detects the small difference and amplifies the difference to the operating voltage, signaling that a logical 1 was stored in the memory cell 102. Alternatively, if the bit line 118 that is connected to the memory cell 102 has a lower voltage than the other bit line 118, the sense amplifier circuitry 124 detects the difference and amplifies the difference to the reference voltage, signaling that a logical 0 was stored in the memory cell 102.

The driving of an access line 116 may be at a higher voltage than the voltage of the address signals 122 received by the row decoder 120. Accordingly, a voltage level shifter may be used to convert the address signal from a first power domain to a second power domain.

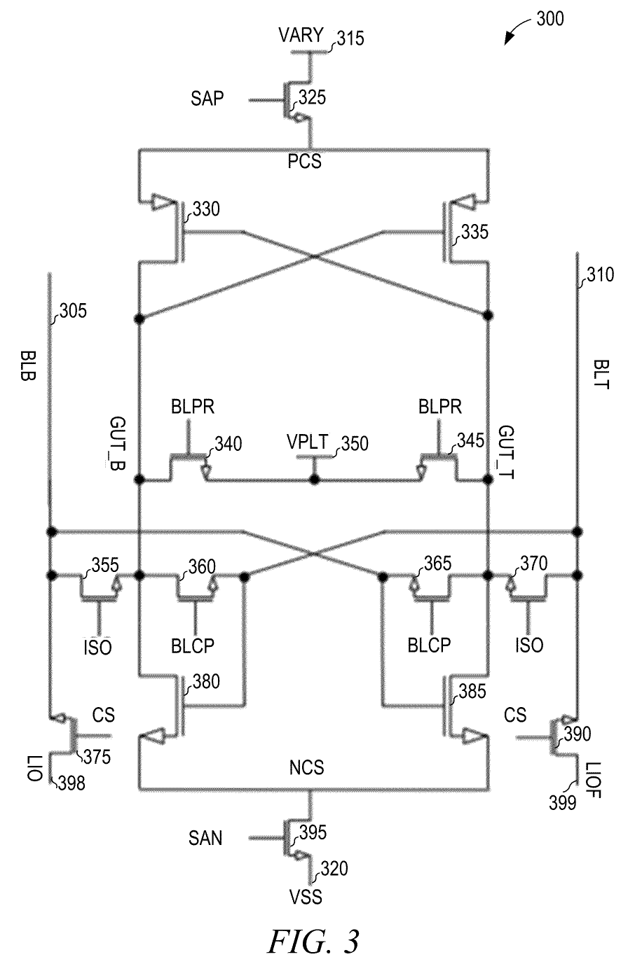

The memory device 100 may be implemented as an integrated circuit within a package that includes pins for receiving supply voltages (e.g., to provide the source and gate voltages for the transistors 110) and signals (including data, address, and control signals). In general, it is to be understood that FIG. 1 depicts memory device 100 in drastically simplified form to illustrate basic structural components and principles of operation, omitting many details of the memory cells 102 and associated access and data lines 116, 118 as well the row and column decoders 120, 130, sense amplifier circuitry 124, and buffers 126. Additional details regarding the sense amplifier circuitry 124 are described below with respect to FIGS. 3-10. The memory device 100 may include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein. Instead, the following description focuses on structural details of the memory cells 102 and layout of the memory cell array in accordance with various embodiments.

In 2D DRAM arrays, the rows 104 and columns 106 of memory cells 102 are arranged along a single horizontal plane (i.e., a plane parallel to the layers) of the semiconductor substrate, e.g., in a rectangular lattice with mutually perpendicular horizontal access and data lines 116, 118. In 3D DRAM arrays, the memory cells 102 are arranged in a 3D lattice that encompasses multiple vertically stacked horizontal planes corresponding to multiple device tiers of a multi-tier substrate assembly, with each device tier including multiple parallel rows of cells 102 whose transistor gate terminals are connected by horizontal access lines 116. (A “device tier,” as used herein, may include multiple layers (or levels) of materials, but forms the components of memory devices of a single horizontal tier of memory cells.) The data lines 118 extend vertically through all or at least a vertical portion of the multi-tier structure, and each data line 118 connects to the transistor source terminals of a vertical column 106 of associated memory cells 102 at the multiple device tiers. This 3D configuration of memory cells enables further increases in bit density compared with 2D arrays.

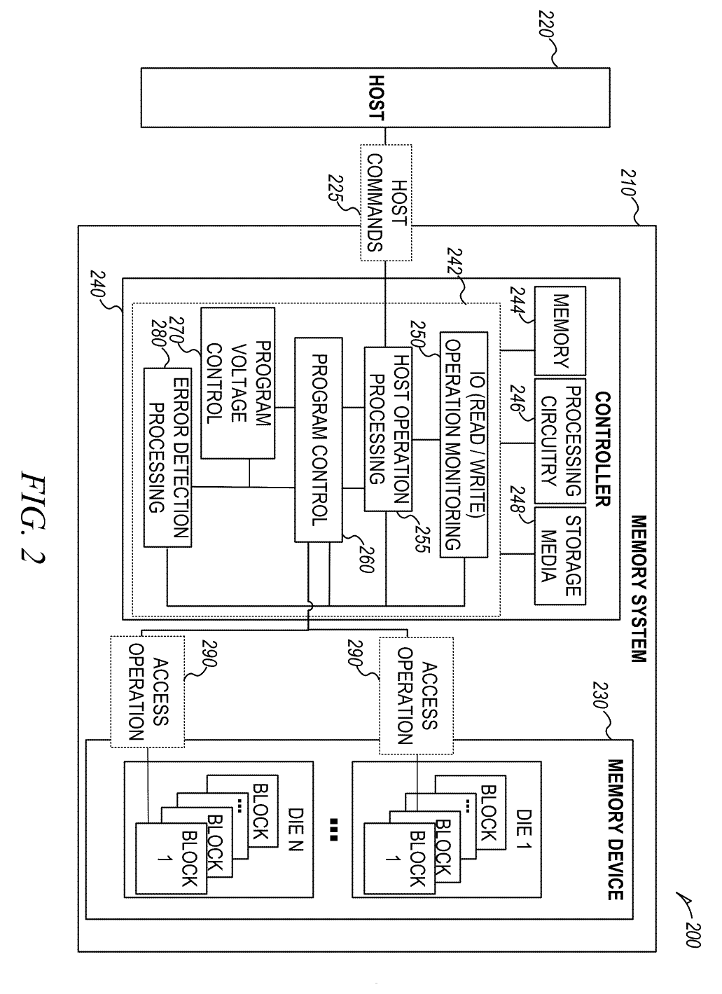

FIG. 2 provides a block diagram of an example system 200 including a memory system 210 (e.g., a SSD storage device, a SD/MMC card, etc.) having a memory controller 240 and a memory device 230. In an example, the functionality of control modules 242 of the memory controller 240 may be implemented in respective modules in a firmware of the memory controller 240. However, it will be understood that various forms of software, firmware, and hardware may be utilized by the controller 240 to implement the control modules 242 (e.g., implement the functionality of program control 260) and the other techniques discussed herein.

As shown, the memory system 210 includes a DRAM memory device 230 with multiple dies (dies 1-N), with each die including one or more blocks (blocks 1-N). Each of the one or more blocks may include further divided portions, such as one or more wordlines (not shown) per block; and each of the one or more wordlines may be further comprised of one or more pages (not shown) per wordline, depending on the number of data states that the memory cells of that wordline are configured to store.

Accessing data from the memory device 230 may comprise applying a read voltage to a wordline, wherein the voltage applied to the wordline is different than the signaling voltage used to indicate that the voltage should be applied. A voltage level shifter may be used to convert the signaling voltage in a first power domain to the read voltage in a second power domain.

The memory system 210 is shown as being operably coupled to a host 220 via a controller 240 of the memory device. The controller 240 is adapted to receive and process host IO commands 225, such as read commands, write commands, erase commands, and the like, to read, write, erase, and manage data stored within the memory device 230. In other examples, the memory controller 240 may be physically separate from an individual memory device, and may receive and process commands for one or more individual memory devices. A variety of other components for the memory system 210 (such as a memory manager, and other circuitry or operational components) and the controller 240 are also not depicted for simplicity.

The controller 240 is depicted as including a memory 244 (e.g., volatile memory), processing circuitry 246 (e.g., a microprocessor), and a storage media 248 (e.g., non-volatile memory), used for executing instructions (e.g., instructions hosted by the storage media 248, loaded into memory 244, and executed by the processing circuitry 246) to implement the control modules 242 for management and use of the memory device 230. The functionality provided by the control modules 242 may include, but is not limited to: IO operation monitoring 250 (e.g., to monitor read and write IO operations, originating from host commands); host operation processing 255 (e.g., to interpret and process the host IO commands 225, and to issue further commands to the memory device 230 to perform respective read, write, erase, or other host-initiated operations); program control 260 (e.g., to control the timing, criteria, conditions, and parameters of respective access operations 290 on the memory device 230); program voltage control 270 (e.g., to establish, set, and utilize a program voltage level to program a particular portion of the memory device 230); and error detection processing 280 (e.g., to identify and correct errors from data obtained in read operations, to identify one or more raw bit error rates (RBER(s)) for a particular read operation or set of operations, etc.).

One or more communication interfaces can be used to transfer the host IO commands 225 between the memory system 210 and one or more other components of the host 220, such as a Serial Advanced Technology Attachment (SATA) interface, a Peripheral Component Interconnect Express (PCIe) interface, a Universal Serial Bus (USB) interface, a Universal Flash Storage (UFS) interface, an eMMC™ interface, or one or more other connectors or interfaces. The host 220 can include a host system, an electronic device, a processor, a memory card reader, or one or more other electronic devices external to the memory system 210.

In an example, the host operation processing 255 is used to interpret and process the host IO commands 225 (e.g., read and write commands) and initiate accompanying commands in the controller 240 and the memory device 230 to accomplish the host IO commands 225. Further, the host operation processing 255 may coordinate timing, conditions, and parameters of the program control 260 in response to the host IO commands 225, IO operation monitoring 250, and error detection processing 280.

The IO operation monitoring 250 operates, in some example embodiments, to track reads and writes to the memory device 230 initiated by host IO commands. The IO operation monitoring 250 also operates to track accompanying IO operations and states, such as a host IO active or inactive state (e.g., where an active state corresponds to the state of the controller 240 and memory device 230 actively performing read or write IO operations initiated from the host 220, and where an inactive state corresponds to an absence of performing such IO operations initiated from the host 220). The IO operation monitoring 250 may also monitor voltage level and read error rates occurring with the IO operations initiated from the host 220, in connection with determining parameters for the program control 260 as discussed herein.

The program control 260 can include, among other things, circuitry or components (hardware and/or software) configured to control memory operations associated with writing data to, reading data from, or erasing one or more memory cells of the memory device 230 coupled to the memory controller 240. The controller 240 may access the memory cells of the memory device 230 using access operations 290, such as reads, writes, erases, and the like.

The program voltage control 270, in some example embodiments, is used to establish, change, and provide a voltage value used to program a particular area of memory (such as a respective block in the memory device 230). For example, the program voltage control 270 may implement various positive or negative offsets in order to program respective memory cells and memory locations (e.g., pages, blocks, dies) including the respective memory cells. A voltage level shifter may be used to transition control signals from a first power domain to control signals in a second power domain. The operating voltage of the second power domain may be controlled by the program voltage control 270. For example, a common ground may be used in the two power domains, a fixed voltage source used as the operating voltage of the first power domain, and the output of a voltage source, configured by the program voltage control 270, used as the operating voltage of the second power domain.

The error detection processing 280, in some example embodiments, may detect a recoverable error condition (e.g., a RBER value or an RBER trend), an unrecoverable error condition, or other measurements or error conditions for a memory cell, a group of cells, or larger areas of the memory array (e.g., averages or samples from a block, group of blocks, die, group of dies, etc.).

Additionally, the sampling and read operations that are performed in a read scan by the program control 260 may allow configuration, such as from a specification (e.g., a determined setting or calculation) of: a size of data (e.g., data corresponding to a page, block, group of blocks, die) that is programmed; a number of pages in total that are programmed; a number of pages within a block that are programmed; whether certain cells, pages, blocks, dies, or certain types of such cells, pages, blocks, dies are or are not programmed; and the like. Likewise, the program control 260 may control or allow configuration of the number of program cycles that are performed before the first verify cycle, the number of program cycles that are performed between verify cycles, the number of bits to be successfully programmed at each level before next-level verification begins, or any suitable combination thereof.

In addition to the techniques discussed herein, other types of maintenance operations may be implemented by the control modules 242 in the controller 240. Such operations may include garbage collection or reclamation, wear leveling, block management, and other forms of background activities performed upon the memory device 230. Such background activities may be triggered during an idle state detected by the IO operation monitoring 250, such as immediately following or concurrently with a read scan operation.

The program control 260 can include an error correction code (ECC) component, which can include, among other things, an ECC engine or other circuitry configured to detect or correct errors associated with writing data to or reading data from one or more memory cells of the memory device 230 coupled to the memory controller 240. The memory controller 240 can be configured to actively detect and recover from error occurrences (e.g., bit errors, operation errors, etc.) associated with various operations or storage of data, while maintaining integrity of the data transferred between the host 220 and the memory system 210, or maintaining integrity of stored data (e.g., using redundant RAID storage, etc.), and can remove (e.g., retire) failing memory resources (e.g., memory cells, memory arrays, pages, blocks, etc.) to prevent future errors.

FIG. 3 illustrates an example DRAM sense amplifier 300 for use in a DRAM device. The sense amplifier 300 is coupled to BLB 305 and BLT 310, also referred to as differential bit line inputs 305 and 310; voltage sources 315, 320, and 350; and output signal lines 398 and 399. The sense amplifier 300 comprises transistors 325, 330, 335, 340, 345, 355, 360, 365, 370, 375, 380, 385, 390, and 395. The DRAM sense amplifier 300 receives control signals SAP, SAN, BLPR, BLCP, ISO, and CS. The voltage source 315 provides the operating voltage (e.g., 1.0V). The voltage source 320 provides a reference voltage (e.g., 0.0V). The voltage source 350 provides a neutral voltage (e.g., halfway between the operating voltage and the reference voltage, or 0.5 V).

As input, if the voltage on BLT 310 is higher than the voltage on BLB 305, this indicates that the memory cell holds a 1 value. If the voltage on BLT 310 is lower than the voltage on BLB 305, this indicates that the memory cell holds a 0 value. As output, if the memory cell holds a 1 value, the output signal line 399 should be set to the operating voltage from the voltage source 315 and the output signal line 398 should be set to the reference voltage from the voltage source 320. If the memory cell holds a 0 value, the output signal line 398 should be set to the operating voltage from the voltage source 315 and the output signal line 399 should be set to the reference voltage from the voltage source 320.

During an idle state, BLPR and ISO are active signals; SAP and SAN are inactive. As a result, the voltage source 350 is connected to BLB 305, BLT 310, and the lines GUT_B and GUT_T. Thus, much of the internal circuitry of the sense amplifier 300 is held at a neutral voltage during the idle state.

When data is read from a memory cell, charge from capacitors for the memory cell flows to the differential bit line inputs 305 and 310. The transistors 330, 335, 380, and 385 operate as a differential amplifier. The differential amplifier amplifies the small charge difference between the two differential bit line inputs 305 and 310 up to the operating voltage. After the differential amplifier has adjusted the voltages on the BLB and BLT lines 305 and 310, the CS signal enables the transistors 375 and 390, allowing the outputs to be provided on the output signal lines 398 and 399.

Due to physical variations in production of the components of the sense amplifier 300, the transistors comprising the sense amplifier 300 may have different threshold voltages, which may cause incorrect results. To compensate, an offset cancellation phase is added between the idle state and the data read operation. During the offset cancellation phase, BLPR and ISO are deactivated, and SAN and BLCP are activated. As a result, the drain and gate of the transistor 385 are connected, which results in the voltage at that connection stabilizing at the threshold voltage of the transistor 385. This junction is also connected to the bit line BLB 305. Thus, rather than initializing the bit line BLB 305 to the nominal neutral voltage provided by the voltage source 350, the bit line BLB 305 is initialized to the actual threshold voltage of the transistor 385. The circuit is symmetrical, and thus BLT 310 is initialized to the threshold voltage of the transistor 380.

The offset cancellation phase improves the operation of the sense amplifier 300 by biasing one or both of the differential bit line inputs 305 and 310 before charge sharing begins. However, the voltage change caused by the charge sharing is impacted by the starting voltage. Thus, the voltage change on one of BLB 305 and BLT 310 may be less than the voltage change on the other, reducing the efficacy of the differential amplifier. Furthermore, since variation also occurs in the memory cells themselves, some memory cells may still fail to be read correctly even with the offset cancellation.

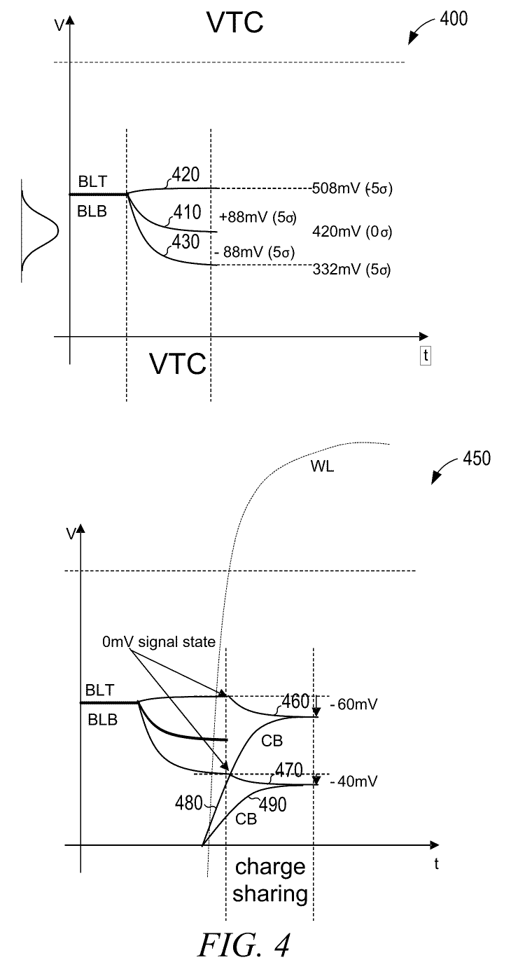

FIG. 4 illustrates a first graph 400 showing a range of potential voltage offsets in a sense amplifier (e.g., the sense amplifier 300) due to device variation, and a second graph 450 showing that even after compensating for the voltage offsets, charge sharing is affected by the device variation in a DRAM sense amplifier.

The first graph 400 shows a nominal threshold voltage 410 of 420 mV for a particular sense amplifier. Due to device variation in the sense amplifier, the actual threshold voltage may vary. For example, at 5σ, the threshold voltage may vary by +/- 88 mV. The example of the first graph 400 includes a first threshold voltage 420 showing the + offset, at 508 mV, and includes a second threshold voltage 430 showing the – offset, at 332 mV. In other words, due to statistical variabilities in the devices that comprise sense amplifiers, a digit line for one sense amplifier may indicate “0” at 332 mV while a digit line for another sense amplifier may indicate “0” at 508 mV.

The second graph 450 shows the effect of charge sharing after a wordline signal is raised. When the capacitor of the memory cell is discharged into the bit line, the voltage of the capacitor and the bit line come to equilibrium. The curves 480 and 490 show the voltage at the capacitor and the curves 460 and 470 show the voltage on the bit line. In this example, the capacitor is storing a logical 0 value. When the capacitor is connected to the bit line, the voltage on the bit line drops, as charge flows into the capacitor. When the bit line begins with a higher voltage, the equilibrium voltage is higher than when the bit line begins with a lower voltage. As a result, more charge flows from the bit line into the capacitor, and the drop in voltage on the bit line is greater. Thus, the curves 460 and 480 reach equilibrium 60 mV below the initial voltage and the curves 470 and 490 reach equilibrium 40 mV below the initial voltage.

In the second graph 450, the effect of charge sharing a logical 0 with a -5σ device is smaller than the effect of charge sharing with a nominal device (or a +5σ device). Sharing a logical 1 will raise the voltage on the bit line, and thus will have a smaller effect with a +5σ device than with a nominal or -5σ device.

Using the sense amplifier 300 of FIG. 3, each bit line is compensated for separately. Accordingly, if one of the transistors 380 and 385 has a voltage offset at +5 σ and the other one has a voltage offset at -5 σ, the sense amplifier 300 will have difficulty in correctly detecting one of the two bit values, because the voltage on both of the bit lines will change by less than the nominal amounts when that bit value is stored.

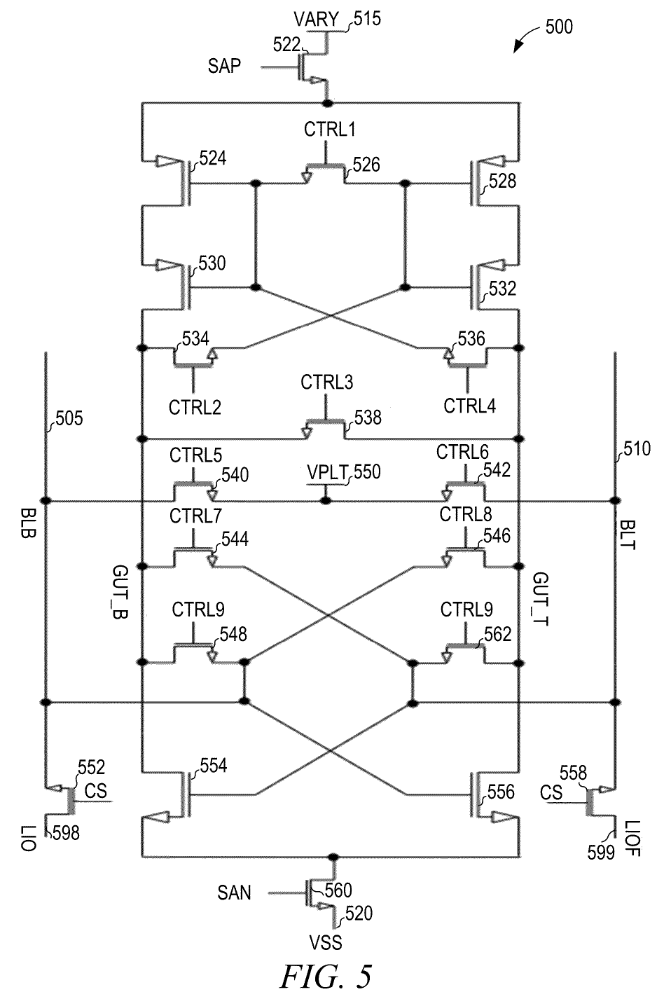

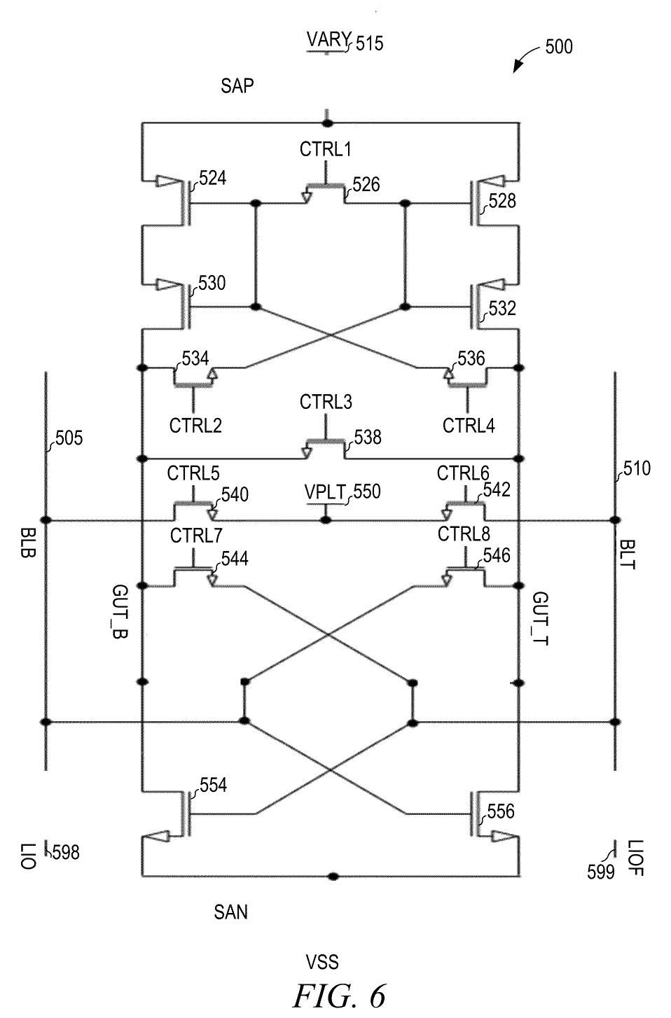

FIGS. 5-9 illustrate an example DRAM differential latch sense amplifier 500 for use in a DRAM device. FIG. 5 shows transistors of the differential latch sense amplifier 500. When operating as digital components, transistors either act as wires or as open circuits, depending on the voltage supplied to the gate. FIGS. 6-9 show the circuit of FIG. 5, with some transistors removed to show their operation as open circuits. The differential latch sense amplifier 500 is coupled to BLB 505 and BLT 510, also referred to as differential bit line inputs 505 and 510; voltage sources 515, 520, and 550; and output signal lines 598 and 599. The differential latch sense amplifier 500 comprises transistors 522, 524, 526, 528, 530, 532, 534, 536, 538, 540, 542, 544, 546, 548, 552, 554, 556, 558, 560, and 562. The DRAM sense amplifier 300 receives control signals SAP, SAN, CTRL1, CTRL2, CTRL3, CTRL4, CTRL5, CTRL6, CTRL7, CTRL8, CTRL9, and CS. The voltage source 515 provides the operating voltage (e.g., 1.0V). The voltage source 520 provides a reference voltage (e.g., 0.0V). The voltage source 550 provides a neutral voltage (e.g., halfway between the operating voltage and the reference voltage, or 0.5 V).

The SAP and SAN control signals are sense control signals. When activated, they enable the sense amplifier circuit that amplifies a difference between BLB 505 and BLT 510 to the operating voltage. The CS control signal is an output control signal. When activated, CS enables the amplified voltage on BLB 505 or BLT 510 to be accessed by the memory device. The remaining control signals control the internal operations of the DRAM differential latch sense amplifier 500.

The bit line inputs, voltage inputs, and data outputs for the differential latch sense amplifier 500 are the same as those of the sense amplifier 300 of FIG. 3. The transistors 524, 528, 530, 532, 554, and 556 operate as a differential amplifier, similar in function to the transistors 330, 335, 380, and 385 of the sense amplifier 300. However, the additional transistors and control signals of the differential latch sense amplifier 500 modify the manner in which voltage offsets of the sense amplifier are detected and compensated for.

A few of the connections shown in FIG. 5 will be described. The differential bit line input 505 is connected to the drain of the transistor 540, the source of the transistors 546 and 548, and the gate of the transistor 556. The differential bit line input 510 is connected to the drain of the transistor 542, the source of the transistors 544 and 562, and the gate of the transistor 554. The source of the transistor 540 is connected to the source of the transistor 542 and to the voltage source 550. The voltage source 520 is connected to the source of the transistor 560. A control signal SAN is connected to the gate of the transistor 560. The drain of the transistor 560 is connected to the sources of the transistors 554 and 556.

The voltage source 515 is connected to the source of the transistor 522. A control signal SAP is connected to the gate of the transistor 522. The drain of the transistor 522 is connected to the source of the transistors 524 and 528. The drain of the transistor 524 is connected to the source of the transistor 530. The drain of the transistor 528 is connected to the source of the transistor 532. In response to assertion of a control signal CTRL1 at the gate of the transistor 526, the gates of the transistors 524, 528, 530, and 532 are connected. The gates of the transistors 524 and 530 are connected to the source of the transistor 526. The gates of the transistors 528 and 532 are connected to the drain of the transistor 526.

The source of the transistor 536 is connected to the gates of the transistors 524 and 530. The source of the transistor 534 is connected to the gates of the transistors 528 and 532. The source of the transistor 538 is connected to the drain of the transistor 534. The drain of the transistor 538 is connected to the drain of the transistor 536.

Referring again to FIG. 1, the memory device 100 includes multiple memory cells (e.g., billions of memory cells). Each pair of adjacent bit lines 118 can be connected to a respective differential latch sense amplifier 500. Since each word line 116 is connected to memory cells on either the even-numbered bit lines 118 or the odd-numbered bit lines 118, the number of differential latch sense amplifiers 500 is one-half the number of bit lines 118.

In an example, the differential latch sense amplifier 500 is connected to a first bit line that shares charge with a memory cell and a second bit line that does not share charge with the memory cell. Which one of the differential bit line inputs 505 and 510 shares charge with a memory cell depends on which word line is energized. For example, if the differential bit line input 505 is connected to a memory cell when even-numbered word lines are activated, the differential bit line input 510 will be connected to a memory cell when odd-numbered word lines are activated.

During an idle state, as shown in FIG. 6, control signals CTRL5, CTRL6, CTRL9, and ISO are active signals (i.e., asserted); SAP and SAN are inactive (i.e., unasserted). As a result, the voltage source 550 is connected to BLB 505, BLT 510, and the lines GUT_B and GUT_T. Thus, much of the internal circuitry of the differential latch sense amplifier 500 is held at a neutral voltage during the idle state.

When data is read from a memory cell, charge from capacitors for the memory cell flows to the differential bit line inputs 505 and 510. The transistors 524, 528, 530, 532, 554, and 556 operate as a differential amplifier. The differential amplifier amplifies the small charge difference between the two differential bit line inputs 505 and 510 up to the operating voltage. After the differential amplifier has adjusted the voltages on the BLB and BLT lines, the CS signal enables the transistors 552 and 558, allowing the outputs to be received on the output signal lines 598 and 599.

Due to variations in production, the transistors comprising the sense amplifier may have different threshold voltages, which may cause incorrect results. To compensate, an offset cancellation phase is added between the idle state and the data read operation.

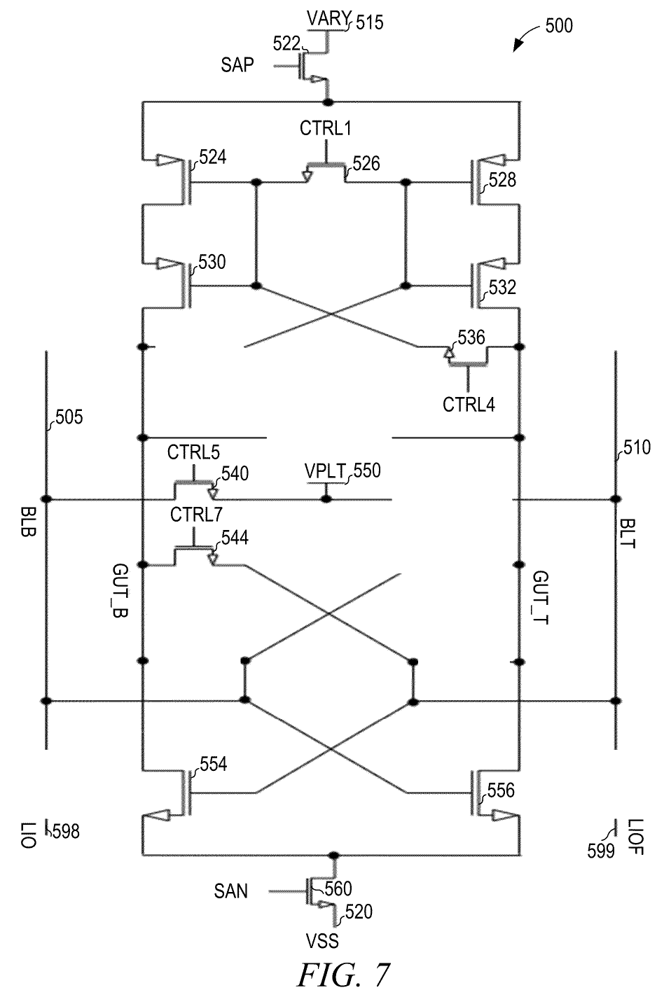

FIG. 7 shows the offset cancellation phase of the differential latch sense amplifier 500. Prior to the offset cancellation phase, the differential latch sense amplifier 500 was in an idle state. Accordingly, the differential bit line inputs 505 and 510 are initialized to VPLT from the voltage source 550. If there is no offset to compensate for, the differential amplifier composed of the transistors 524, 528, 530, 532, 554, and 556 will detect no difference in voltage between the differential bit line inputs 505 and 510 when VPLT is disconnected from the differential bit line input 510. Accordingly, the differential amplifier will not modify the voltages on the differential bit line inputs 505 and 510.

However, if there is a voltage offset in the differential amplifier, there will be a difference between the constant voltage being supplied to the differential bit line input 505 and the measured voltage from the differential bit line input 510. The differential amplifier will adjust the voltage on the differential bit line input 510 until the voltages of the two differential bit line input 505-510, as measured by the differential amplifier, are equal. Thus, unlike the sense amplifier of FIG. 3, only one bit line is adjusted during the offset cancellation phase.

Thus, the differential latch sense amplifier 500 includes a voltage offset determining portion that determines a total voltage offset for the first bit line and the second bit line and a voltage adjustment portion that applies the total voltage offset to the second bit line to generate an adjusted second voltage. The voltage offset determining portion includes the differential amplifier including the transistors 524, 528, 530, 532, 554, and 556. The differential amplifier may also include a first input connected to the first differential bit line input 505 and a second input connected to the second differential bit line input 510. For example, in FIG. 7, the differential bit line input 505 is connected via wires to the gate of the transistor 556, and the connections form a first input. The differential bit line input 510 is connected via other wires to the gate of the transistor 554, and the other connections form a second input.

The total voltage adjustment using the circuit of FIGS. 5-9 is less than or equal to the total voltage adjustment using the circuit of FIG. 3. The total adjustment is equal when the offset for each bit line has an opposite sign. For example, if the offset for the differential bit line input 305 is + 88mV and the offset for the differential bit line input 310 is -88mV, the circuit of FIG. 3 will adjust the voltage of each bit line 305-310 by 88 mV. If the offset for the differential bit line input 505 is + 88mV and the offset for the differential bit line input 510 is -88mV, the circuit of FIG. 3 will adjust the voltage of each the differential bit line input 510 by 176 mV, the same total adjustment.

However, when the offset for each bit line has the same sign, the total adjustment is lower for the circuit of FIGS. 5-9. For example, if the offset for the differential bit line input 305 is + 88 mV and the offset for the differential bit line input 310 is +44 mV, the circuit of FIG. 3 will adjust the voltage of each bit line 305-310, for a total adjustment of 132 mV. When the offset for the differential bit line input 505 is + 88mV and the offset for the differential bit line input 510 is +44 mV, the circuit of FIG. 5 will adjust the voltage of the differential bit line input 510 only by the difference, 44 mV.

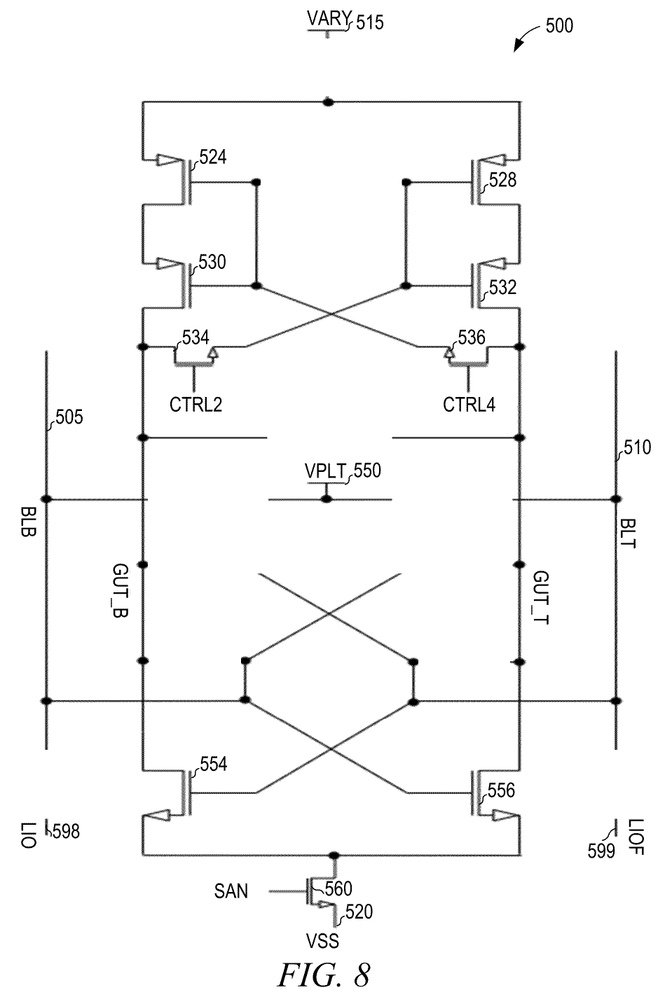

After the offset cancellation phase is complete, the word line for the memory cell being read is activated, causing charge sharing to begin between the capacitors for the memory cell and the differential bit line inputs 505 and 510. The appropriate connections for charge sharing are shown in FIG. 8.

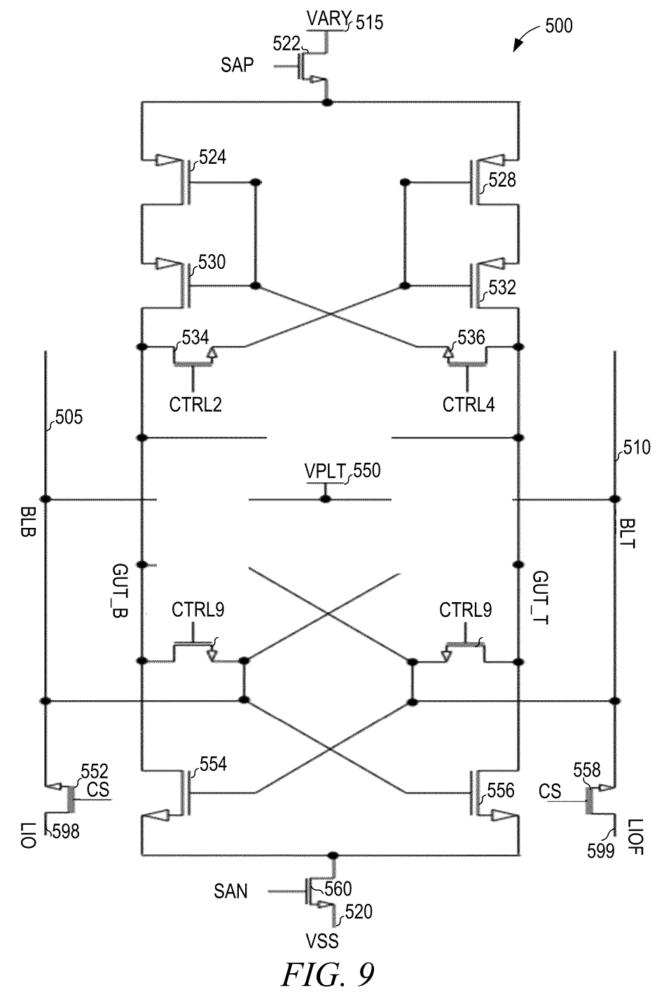

FIG. 9 shows the latching phase of the differential latch sense amplifier 500. In this phase, the differential amplifier of the transistors 524, 528, 530, 532, 554, and 556 amplifies the small voltage differential on the differential bit line inputs 505 and 510 and provides a signal at the operating voltage from the voltage source 515 on one of the outputs 598-599 and a signal at the reference voltage from the voltage source 520 on the other one of the outputs 598-599. Thus, the differential latch sense amplifier 500 includes a voltage comparison portion that compares a first voltage of the first bit line to the adjusted second voltage of the second bit line to determine a value of the memory cell.

The transistors 548 and 562 connect the differential bit line inputs 505 and 510 to the output signals from the differential amplifier and the transistors 552 and connect the differential bit line inputs 505 and 510 to the output signal lines 598 and 599. Accordingly, the differential latch sense amplifier 500 includes an output connected to the differential bit line input 505 and an output connected to the second differential bit line input 510.

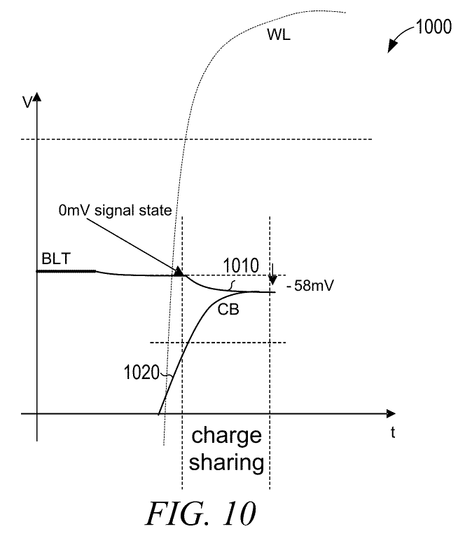

FIG. 10 illustrates a graph 1000 showing a constant voltage offset device and its effect on charge sharing in a DRAM differential latch sense amplifier. As discussed above with respect to FIGS. 5-9, the DRAM differential latch sense amplifier maintains one bit line at a neutral voltage provided by the voltage source 550. The other bit line is adjusted according to the difference in threshold voltages of the transistors that make up the differential amplifier. Accordingly, device variation in the differential amplifiers does not affect the voltage at which the bit line is kept before charge sharing begins. As a result, the voltage differential as a result of charge sharing is fixed.

The graph 1000 shows the effect of charge sharing after a word line signal is raised. When the capacitor of the memory cell is discharged into the bit line, the voltage of the capacitor and the bit line come to equilibrium. The curve 1020 shows the voltage at the capacitor and the curve 1010 shows the voltage on the bit line. In this example, the capacitor is storing a logical 0 value. When the capacitor is connected to the bit line, the voltage on the bit line drops, as charge flows into the capacitor. The curves 1010 and 1020 reach equilibrium 58 mV below the initial voltage.

In the graph 450 of FIG. 4, the effect of charge sharing a logical 0 with a -5σ device is smaller than the effect of charge sharing with a nominal device (or a +5σ device). Sharing a logical 1 will raise the voltage on the bit line, and thus will have a smaller effect with a +5σ device than with a nominal or -5σ device. However, in the graph 1000, the effect of charge sharing with a + or - 5σ device is the same as the effect of charge sharing with a nominal device.

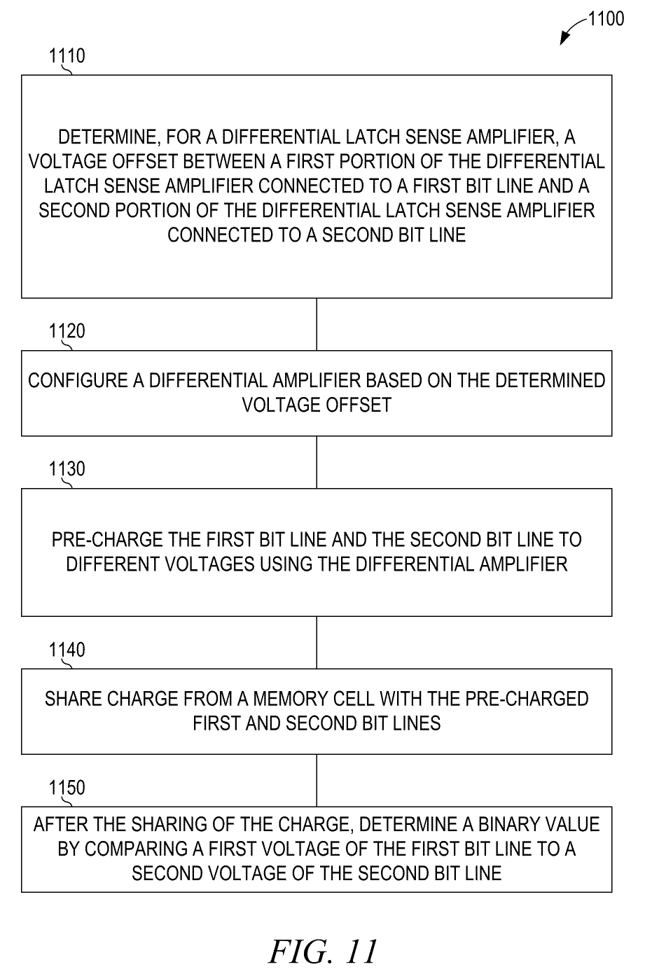

FIG. 11 is a flow chart showing operations of a method 1100 performed by a DRAM differential latch sense amplifier, in accordance with some embodiments of the present disclosure. The method 1100 includes steps 1110, 1120, 1130, 1140, and 1150. By way of example and not limitation, the method 1100 is described as being performed by the differential latch sense amplifier 500 of FIGS. 5-9.

In step 1110, the differential latch sense amplifier 500 determines a voltage offset between a first portion of the differential latch sense amplifier 500 connected to a first bit line (e.g., the differential bit line input 505) and a second portion of the differential latch sense amplifier 500 connected to a second bit line (e.g., the differential bit line input 510). The voltage offset may be a difference in activation energies for the gates of two transistors.

In step 1120, the differential latch sense amplifier 500 configures a differential amplifier based on the determined voltage offset. In FIGS. 5-9, the differential amplifier includes transistors 524, 528, 530, 532, 554, and 556. The determined voltage offset may be a voltage offset of components of the differential amplifier.

In step 1130, the differential latch sense amplifier 500 pre-charges the first bit line and the second bit line to different voltages using the differential amplifier. For example, the differential bit line input 505 may be pre-charged to the voltage provided by the voltage source 550 and the differential bit line input 510 may be pre-charged a modified voltage. The modified voltage may be the voltage provided by the voltage source 550 adjusted by a difference in the activation energies of the transistors 554 and 556.

The memory device 100, in step 1140, shares charge from a memory cell with the pre-charged first and second bit lines. The sharing of charge may be in response to activation of a word line. The method 1100 may be simultaneously performed by many differential latch sense amplifiers 500, one for each bit in a word of the memory device 100. When the word line is activated, the charge from each memory cell is shared with the bit lines of a corresponding differential latch sense amplifier 500.

At step 1150, after the sharing of the charge, the differential latch sense amplifier 500 determines a binary value by comparing a first voltage of the first bit line to a second voltage of the second bit line. Each differential latch sense amplifier 500 provides a single digital bit.

By using the method 1100, the accuracy of the digital output in step 1150 is improved for transistors that vary substantially from the mean. In devices that comprise millions, billions, or trillions of memory cells, the total number of memory cells that are usable using the method 1100 may be substantially higher than those that are usable with prior art methods.

To better illustrate the methods and apparatuses described herein, a non-limiting set of Example embodiments are set forth below as numerically identified Examples.

Example 1 is a memory device comprising: a memory cell; and a differential latch sense amplifier connected to a first bit line that shares charge with the memory cell and a second bit line that does not share charge with the memory cell, the differential latch sense amplifier comprising: a voltage offset determining portion that determines a total voltage offset for the first bit line and the second bit line; a voltage adjustment portion that applies the total voltage offset to the second bit line to generate an adjusted second voltage; and a voltage comparison portion that compares a first voltage of the first bit line to the adjusted second voltage to determine a value of the memory cell.

In Example 2, the subject matter of Example 1 includes an output portion that is connected to the voltage comparison portion of the differential latch sense amplifier to provide a binary indication of a data value stored by the memory cell.

In Example 3, the subject matter of Examples 1–2, wherein the voltage adjustment portion comprises a differential amplifier.

In Example 4, the subject matter of Example 3, wherein the differential amplifier comprises a first input connected to the first bit line and a second input connected to the second bit line.

In Example 5, the subject matter of Example 4, wherein the differential amplifier comprises an output connected to the second bit line.

In Example 6, the subject matter of Examples 1–5, wherein the differential latch sense amplifier comprises: a first transistor, the first bit line connected to a source of the first transistor; and a second transistor, the first bit line connected to a gate of the second transistor.

In Example 7, the subject matter of Example 6, wherein the differential latch sense amplifier comprises: a third transistor, the second bit line connected to a source of the third transistor; and a fourth transistor, the second bit line connected to a gate of the fourth transistor.

In Example 8, the subject matter of Example 7, wherein the differential latch sense amplifier comprises: a fifth transistor, the first bit line connected to a source of the fifth transistor; and a sixth transistor, the first bit line connected to a drain of the sixth transistor.

In Example 9, the subject matter of Example 8, wherein the differential latch sense amplifier comprises: a seventh transistor, the second bit line connected to a source of the seventh transistor; and an eighth transistor, the second bit line connected to a drain of the eighth transistor.

In Example 10, the subject matter of Example 9, wherein a source of the sixth transistor is connected to a source of the eighth transistor.

In Example 11, the subject matter of Examples 7–10, wherein the differential latch sense amplifier comprises: a fifth transistor, a source of the second transistor connected to a drain of the fifth transistor, a source of the fourth transistor connected to the drain of the fifth transistor, a control signal connected to a gate of the fifth transistor, and a voltage source connected to the source of the fifth transistor.

In Example 12, the subject matter of Examples 1–11, wherein the differential latch sense amplifier comprises: a first transistor, wherein a voltage source is connected to a drain of the first transistor and a control signal is connected to a gate of the first transistor; a second transistor, wherein a source of the first transistor is connected to a source of the second transistor; a third transistor, wherein a drain of the second transistor is connected to a source of the third transistor; a fourth transistor, wherein the source of the first transistor is connected to a source of the fourth transistor; and a fifth transistor, wherein a drain of the fourth transistor is connected to a source of the fifth transistor.

In Example 13, the subject matter of Example 12, wherein the differential latch sense amplifier comprises: a sixth transistor configured to selectively couple the respective gate terminals of the second, third, fourth, and fifth transistors.

In Example 14, the subject matter of Example 13, wherein a gate of the fourth transistor is connected to a source of the sixth transistor and a gate of the fifth transistor is connected to the source of the sixth transistor.

In Example 15, the subject matter of Example 14, wherein the differential latch sense amplifier comprises: a seventh transistor, wherein a source of the seventh transistor is connected to the gate of the fourth transistor.

Example 16 is a method comprising: determining, for a differential latch sense amplifier, a voltage offset between a first portion of the differential latch sense amplifier connected to a first bit line and a second portion of the differential latch sense amplifier connected to a second bit line; and pre-charging the second bit line and the first bit line to different voltages based on the voltage offset.

In Example 17, the subject matter of Example 16 includes configuring a differential amplifier based on the determined voltage offset, wherein the pre-charging of the second bit line and the first bit line includes using the differential amplifier.

In Example 18, the subject matter of Example 17 includes sharing charge from a memory cell with the pre-charged first and second bit lines; and after the sharing of the charge, determining a value of the memory cell based on a comparison of a first voltage of the first bit line to a second voltage of the second bit line.

In Example 19, the subject matter of Example 18 includes providing a comparison result indicating the value of the memory cell, wherein the comparison result comprises a differential voltage signal.

Example 20 is a memory device comprising: a memory cell; and a sense amplifier coupled to a first bit line that shares charge with the memory cell and a second bit line that does not share charge with the memory cell; wherein in a first phase of a sense operation, first devices of the sense amplifier are configured as a differential amplifier to measure an offset characteristic of the sense amplifier, and wherein in a second phase of the sense operation, at least a portion of the same first devices of the sense amplifier are configured to provide information about a charge stored in the memory cell, and the information about the charge stored in the memory cell is based in part on the measured offset characteristic.

Example 21 is an apparatus comprising means to implement any of Examples 1–20.

The above detailed description includes references to the accompanying drawings, which form a part of the detailed description. The drawings show, by way of illustration, specific embodiments in which the inventive subject matter can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” and the like are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the inventive subject matter should be determined with reference to the appended claims, along with the full scope of equivalents to which such claims are entitled.

What is claimed is:

1. A memory device comprising:
a memory cell; and
a differential latch sense amplifier connected to a first bit line that shares charge with the memory cell and a second bit line that does not share charge with the memory cell, the differential latch sense amplifier comprising:
a voltage offset determining portion that determines a total voltage offset for the first bit line and the second bit line;
a voltage adjustment portion that applies the total voltage offset to the second bit line to generate an adjusted second voltage; and
a voltage comparison portion that compares a first voltage of the first bit line to the adjusted second voltage to determine a value of the memory cell.

2. The memory device of claim 1, further comprising an output portion that is connected to the voltage comparison portion of the differential latch sense amplifier to provide a binary indication of a data value stored by the memory cell.

3. The memory device of claim 1, wherein the voltage adjustment portion comprises a differential amplifier.

4. The memory device of claim 3, wherein the differential amplifier comprises a first input connected to the first bit line and a second input connected to the second bit line.

5. The memory device of claim 4, wherein the differential amplifier comprises an output connected to the second bit line.

6. The memory device of claim 1, wherein the differential latch sense amplifier comprises: a first transistor, the first bit line connected to a source of the first transistor; and a second transistor, the first bit line connected to a gate of the second transistor.

7. The memory device of claim 6, wherein the differential latch sense amplifier comprises:
a third transistor, the second bit line connected to a source of the third transistor; and a fourth transistor, the second bit line connected to a gate of the fourth transistor.

8. The memory device of claim 7, wherein the differential latch sense amplifier comprises:
a fifth transistor, the first bit line connected to a source of the fifth transistor; and a sixth transistor, the first bit line connected to a drain of the sixth transistor.

9. The memory device of claim 8, wherein the differential latch sense amplifier comprises:
a seventh transistor, the second bit line connected to a source of the seventh transistor; and an eighth transistor, the second bit line connected to a drain of the eighth transistor.

10. The memory device of claim 9, wherein a source of the sixth transistor is connected to a source of the eighth transistor.

11. The memory device of claim 7, wherein the differential latch sense amplifier comprises:
a fifth transistor, a source of the second transistor connected to a drain of the fifth transistor, a source of the fourth transistor connected to the drain of the fifth transistor, a control signal connected to a gate of the fifth transistor, and a voltage source connected to the source of the fifth transistor.

12. The memory device of claim 1, wherein the differential latch sense amplifier comprises:
a first transistor, wherein a voltage source is connected to a drain of the first transistor and a control signal is connected to a gate of the first transistor;
a second transistor, wherein a source of the first transistor is connected to a source of the second transistor; a third transistor, wherein a drain of the second transistor is connected to a source of the third transistor; a fourth transistor, wherein the source of the first transistor is connected to a source of the fourth transistor; and a fifth transistor, wherein a drain of the fourth transistor is connected to a source of the fifth transistor.

13. The memory device of claim 12, wherein the differential latch sense amplifier comprises:
a sixth transistor configured to selectively couple the respective gate terminals of the second, third, fourth, and fifth transistors.

14. The memory device of claim 13, wherein a gate of the fourth transistor is connected to a source of the sixth transistor and a gate of the fifth transistor is connected to the source of the sixth transistor.

15. The memory device of claim 14, wherein the differential latch sense amplifier comprises:
a seventh transistor, wherein a source of the seventh transistor is connected to the gate of the fourth transistor.

16. A method comprising:
determining, for a differential latch sense amplifier, a voltage offset between a first portion of the differential latch sense amplifier connected to a first bit line and a second portion of the differential latch sense amplifier connected to a second bit line; and
pre-charging the second bit line and the first bit line to different voltages based on the voltage offset.

17. The method of claim 16, further comprising configuring a differential amplifier based on the determined voltage offset, wherein the pre-charging of the second bit line and the first bit line includes using the differential amplifier.

18. The method of claim 17, further comprising:
sharing charge from a memory cell with the pre-charged first and second bit lines; and after the sharing of the charge, determining a value of the memory cell based on a comparison of a first voltage of the first bit line to a second voltage of the second bit line.

19. The method of claim 18, further comprising providing a comparison result indicating the value of the memory cell, wherein the comparison result comprises a differential voltage signal.

20. A memory device comprising:
a memory cell; and
a sense amplifier coupled to a first bit line that shares charge with the memory cell and a second bit line that does not share charge with the memory cell;
wherein in a first phase of a sense operation, first devices of the sense amplifier are configured as a differential amplifier to measure an offset characteristic of the sense amplifier, and
wherein in a second phase of the sense operation, at least a portion of the same first devices of the sense amplifier are configured to provide information about a charge stored in the memory cell, and the information about the charge stored in the memory cell is based in part on the measured offset characteristic.
